(19) United States
(12) Patent Application Publication
(10) Pub. No.: US 2016/0086885 A1
(43) Pub. Date: Mar. 24, 2016

(54) PACKAGE SUBSTRATE

(71) Applicant: IBIDEN CO., LTD., Ogaki-shi (JP)

(72) Inventors: Yasushi INAGAKI, Ogaki-shi (JP); Osamu FUTONAGANE, Ogaki-shi (JP)

(73) Assignee: IBIDEN CO., LTD., Ogaki-shi (JP)

(21) Appl. No.: 14/861,098

(22) Filed: Sep. 22, 2015

(30) Foreign Application Priority Data
Sep. 22, 2014 (JP) 2014-192718

(51) Int. Cl. H01L 23/522; H01L 23/00

(52) U.S. Cl. CPC H01L 23/5226; H01L 24/33; H01L 24/49

(57) ABSTRACT

A package substrate includes resin insulating interlayers, and four or more conductive layers including dedicated wiring layers such that the dedicated wiring layers are two dedicated wiring layers which transmit data between a first electronic component and a second electronic component connected by the two dedicated wiring layers.

### CROSS-REFERENCE TO RELATED APPLICATIONS

The present application is based upon and claims the benefit of priority to Japanese Patent Application No. 2014-192718, filed Sep. 22, 2014, the entire contents of which are incorporated herein by reference.

### BACKGROUND OF THE INVENTION

1. Field of the Invention

The present invention relates to a package substrate for mounting multiple electronic components.

2. Description of Background Art

JP H06-53349A describes a multi-chip module in which two LSIs are mounted on a substrate. The two LSIs are connected through multiple wiring layers. The multiple wiring layers are patterned on different insulation layers. The entire contents of this publication are incorporated herein by reference.

### SUMMARY OF THE INVENTION

According to one aspect of the present invention, a package substrate includes resin insulating interlayers, and four or more conductive layers including dedicated wiring layers such that the dedicated wiring layers are two dedicated wiring layers which transmit data between a first electronic component and a second electronic component connected by the two dedicated wiring layers.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a package substrate according to a first embodiment of the present invention;

FIG. 2 is a cross-sectional view showing an applied example of the package substrate according to the first embodiment;

FIGS. 3A-3C show views of the steps in a method for manufacturing a package substrate of the first embodiment;

FIGS. 4A-4D show views of the steps in the method for manufacturing a package substrate of the first embodiment;

FIGS. 5A-5C show views of the steps in the method for manufacturing a package substrate of the first embodiment;

FIGS. 6A and 6B show views of the steps in the method for manufacturing a package substrate of the first embodiment;

FIGS. 7A-7C show views of the steps in the method for manufacturing a package substrate of the first embodiment;

FIGS. 8A-8C show views of the steps in the method for manufacturing a package substrate of the first embodiment;

FIGS. 9A-9C show views of the steps in the method for manufacturing a package substrate of the first embodiment;

FIG. 10A is a plan view of pad groups and FIG. 10B is a plan view of an applied example;

FIG. 11A is a plan view of a first conductive layer and FIG. 11B is a plan view of an outermost conductive layer;

FIG. 12 is a cross-sectional view of a package substrate according to a second embodiment of the present invention;

FIGS. 13A-13E show views of the steps in a method for manufacturing a package substrate of the second embodiment;

FIG. 14 is a cross-sectional view of a package substrate according to a third embodiment of the present invention; and

FIG. 15 is a cross-sectional view of a package substrate according to a fourth embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

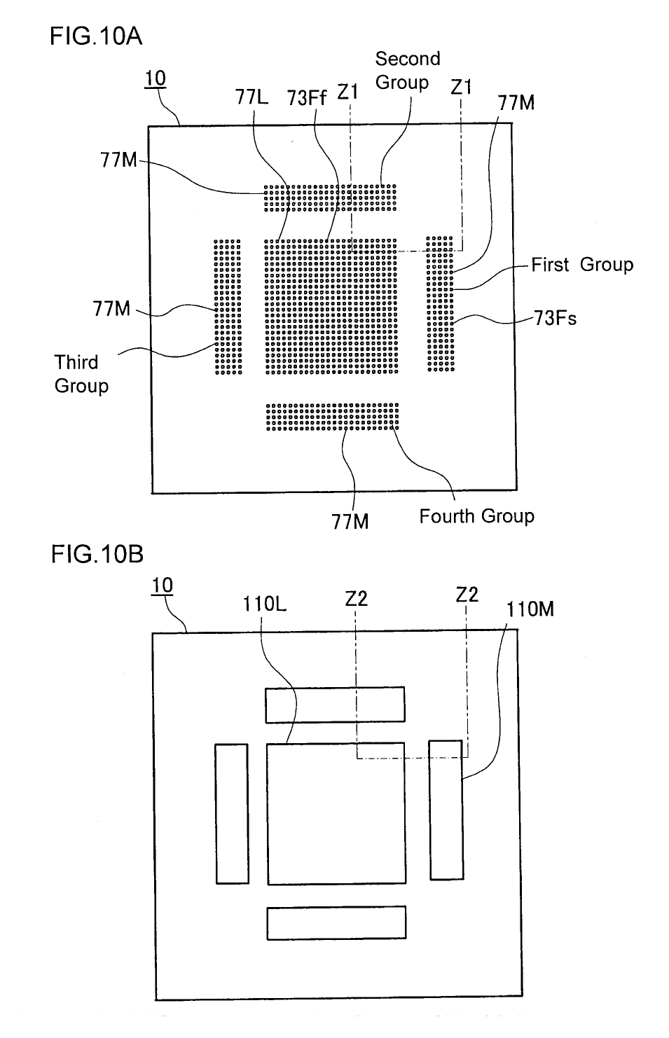

FIG. 10A shows the mounting surface of a package substrate according to a first embodiment of the present invention. FIG. 10B is a plan view of an applied example of the embodiment showing electronic components mounted on the package substrate of the embodiment. As shown in FIG. 10A, mounting region (77L) for mounting a first electronic component such as a logic IC is formed in the central portion of the mounting surface of the package substrate. In mounting region (77L), first pads (73Ff) for mounting a first electronic component are formed in a grid pattern. A first pad group is made up of multiple first pads (73Ff). Solder bumps for mounting a first electronic component are formed on the first pads. Mounting region (77M) for mounting a second electronic component such as a memory is formed on the outer side of mounting region (77L). Four mounting regions (77M) are formed around mounting region (77L) in FIG. 10A. Second pads (73Fs) for mounting a second electronic component are formed in a grid pattern in each mounting region (77M). A second pad group is made up of multiple second pads. Solder bumps for mounting a second electronic component are formed on the second pads. In FIG. 10B, logic IC (110L) is mounted on the solder bumps formed in mounting region (77L), and memory (110M) is mounted on solder bumps formed in mounting region (77M).

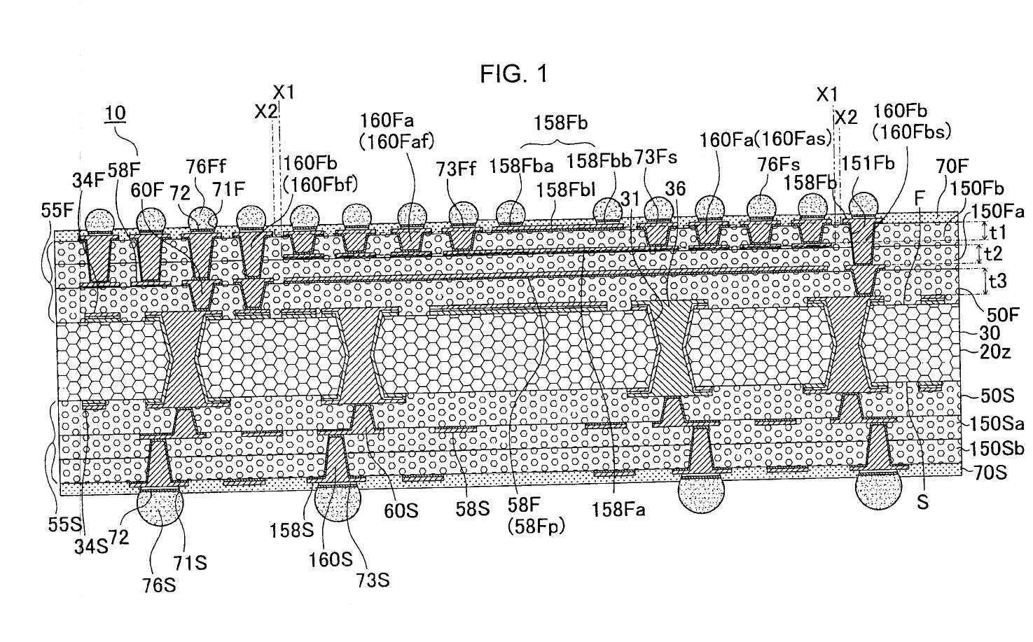

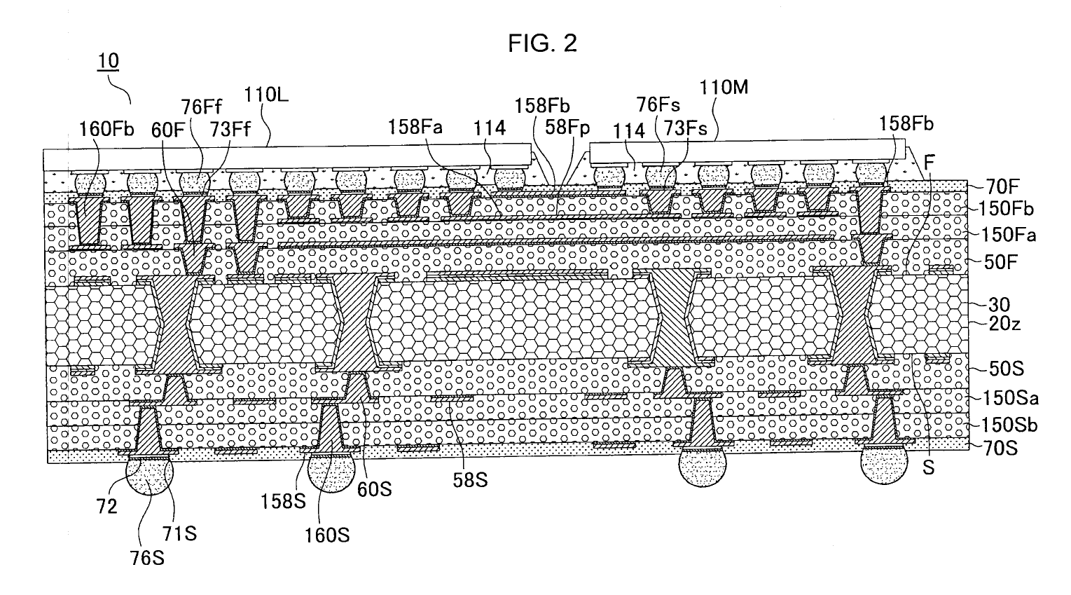

FIG. 1 shows a cross section of the package substrate of the embodiment taken at (Z1-Z1) lines in FIG. 10A. FIG. 2 shows a cross section of an applied example of the embodiment taken at (Z2-Z2) lines in FIG. 10B. Solder bumps (76Ff) for mounting first electronic component (110L) are formed on first pads (73Ff). Solder bumps (76Fs) for mounting second electronic component (110M) are formed on second pads (73Fs).

As shown in FIG. 1, a package substrate of the embodiment is provided with outermost conductive layer (158Fb), which includes the pads for mounting electronic components. The package substrate is further provided with outermost resin insulating interlayer (150Fb), which supports outermost conductive layer (158Fb). Outermost resin insulating interlayer (150Fb) has an upper first surface and a lower second surface.

First via conductors (160Faf) connected to first pads (73Ff) and second via conductors (160Fas) connected to second pads (73Fs) are formed in outermost resin insulating interlayer (150Fb) of the embodiment. A first via conductor is preferred to be formed directly under a first pad. A second via conductor is preferred to be formed directly under a second pad. First conductive layer (158Fa) including multiple first conductive circuits is formed under outermost resin insulating interlayer (150Fb). First pads and second pads are connected by first conductive circuits. Namely, signal transmission or the like between first and second electronic components is carried out through the first conductive layer. Each of the first conductive circuits is set to connect a first pad and a second pad. The conductive circuits formed on the same plane as the first conductive circuits are all included in the first conductive layer. The first conductive layer is set to be a dedicated wiring layer which facilitates signal transmission between first and second electronic components. The first conductive layer includes no other conductive circuits but those conductive circuits (signal lines) for performing signal transmission between first and second electronic components. The first conductive layer works as a dedicated wiring layer which facilitates data transmission between first and second electronic components.

1 bit of data may be transmitted through one signal line (a first conductive circuit). Commands or data in an electronic device such as a personal computer are composed of bytes (8 bits in 1 byte). Different widths or thicknesses of signal lines cause variations in the electrical characteristics of signal lines, such as transmission speed. Accordingly, transmission time is thought to differ among signals in bytes. Signals may not be processed properly, or processing time may be prolonged. Transmission time of each bit in a 1-byte signal is thought to vary. In addition, due to variations in the widths or thicknesses of signal lines, there may be a signal line with slower transmission speeds. Accordingly, such a slow transmission line is thought to cause slow signal processing.

A dedicated wiring layer is formed in the embodiment. When a conductive layer that includes signal lines (dedicated wiring layer) is formed, manufacturing conditions are set based on the width and thickness of the signal lines. Accordingly, signal lines of the embodiment show smaller variations in their widths and thicknesses, thereby achieving substantially the same transmission speed in each signal line. Signals are processed properly. Even a greater volume of data will not cause slower processing speeds. Two dedicated wiring layers based on the functions of electronic components are preferred to be formed in the package substrate of the embodiment. Even if dedicated wiring layers are set in different layers, since each layer contains only data transmission lines, differences in transmission time are small. One conductive layer includes all the conductive circuits sandwiched between two resin insulating interlayers. However, circuits such as dummy conductors that do not transmit signals or power are not counted as conductive circuits.

Inner resin insulating interlayer (150Fa) is formed under the outermost resin insulating interlayer and the first conductive layer (dedicated wiring layer). The outermost resin insulating interlayer and the first conductive layer (dedicated wiring layer) are supported by the inner resin insulating interlayer. In FIG. 1, the conductive circuits sandwiched between the inner resin insulating interlayer and the outermost resin insulating interlayer are all first conductive circuits. The outermost resin insulating interlayer is preferred to be formed directly on the dedicated wiring layer and the inner resin insulating interlayer, because the distance between electronic components and the dedicated wiring layer is reduced.

Second conductive layer (58F) that includes multiple second conductive circuits is formed under inner resin insulating interlayer (150Fa). Power supply and the like to the electronic components are carried out through the second conductive layer. Thus, the first pads and second pads include pads connected to the second conductive layer. Connection between the second conductive layer and the pads connected to the second conductive layer is carried out by skip-via conductors (160Fb). Skip-via conductors (160Fb) are formed in via-conductor openings (151Fb) that penetrate through both outermost resin insulating interlayer (150Fb) and inner resin insulating interlayer (150Fa) at the same time to reach second conductive layer (58F). Skip-via conductors (160Fb) penetrate through the outermost resin insulating interlayer and the inner resin insulating interlayer at the same time.

Since first conductive layer (158Fa) is a dedicated wiring layer, no other via conductor than skip-via conductors penetrates through the inner resin insulating interlayer. The package substrate of the embodiment does not have via conductors that penetrate only through the inner resin insulating interlayer. Therefore, the first conductive layer can spare more space for forming first conductive circuits, thus allowing more first conductive circuits to be formed in the first conductive layer. Accordingly, highly functional electronic components are mounted on the package substrate. A dedicated wiring layer is formed in a single layer, increasing data transmission speed.

A conductive circuit (first conductive layer) in a dedicated wiring layer is set to have a smaller thickness that that of the outermost conductive layer or the second conductive layer. The outermost conductive layer has substantially the same thickness as that of the second conductive layer. For example, the thickness of the first conductive layer is set at 3 μm or greater, that is half or less than half of the thickness of the outermost conductive layer. For example, the thickness of the first conductive layer is approximately 5 μm, and the thickness of the outermost conductive layer and the second conductive layer is approximately 10 μm. By so setting, fine-pitched conductive circuits are formed in the dedicated wiring layer, allowing highly functional electronic components to be mounted on the package substrate.

The first conductive circuits are set to have a narrower width than that of conductive circuits included in the outermost conductive layer or the second conductive layer. Here, the width of a conductive circuit indicates the width of the narrowest conductive circuit in the conductive layer. The width of a first conductive circuit is one-half to two-thirds of the width of a conductive circuit included in the outermost conductive layer or the second conductive layer. For example, the width of a first conductive circuit is approximately 5 μm, whereas the width of a conductive circuit in the outermost conductive layer or the second conductive layer is approximately 9 μm. When a conductive circuit is cut by a plane perpendicular relative to a length direction of the conductive circuit, the minimum distance between the opposing walls is the width of the conductive circuit.

The length (width) of the space between adjacent first conductive circuits is narrower than that of the space between adjacent second conductive circuits. The length of the space between adjacent first conductive circuits is one-half to two-thirds of the length of the space between adjacent second conductive circuits. For example, the length of the space between adjacent first conductive circuits is approximately 5 μm, and the length of the space between adjacent second conductive circuits is approximately 12 μm. Here, the length of a space indicates the length of the narrowest space in the conductive layer. The length of a space is equal to the distance between adjacent conductive circuits.

The package substrate of the embodiment contains a dedicated wiring layer, an outermost resin insulating interlayer formed on the dedicated wiring layer, an outermost conductive layer formed on the outermost resin insulating interlayer and including pads for mounting multiple electronic components, and via conductors penetrating through the outermost resin insulating interlayer to connect the pads and the dedicated wiring layer. Pads include first pads for mounting a first electronic component and second pads for mounting a second electronic component. Moreover, first pads include first pads connected to the dedicated wiring layer and first pads connected to a conductive layer other than the dedicated wiring layer. Also, second pads include second pads connected to the dedicated wiring layer and second pads connected to a conductive layer other than the dedicated wiring layer. Those pads connected to a conductive layer other than the dedicated wiring layer are connected to skip-via conductors. A closed circuit is formed with a first pad connected to the dedicated wiring layer, a signal line in the dedicated wiring layer, and a second pad connected to the dedicated wiring layer. The package substrate of the embodiment may further contain a second conductive layer, an inner resin insulating interlayer on the second conductive layer, and skip-via conductors penetrating through both the outermost resin insulating interlayer and the inner resin insulating interlayer. The dedicated wiring layer is formed on the inner resin insulating interlayer. The dedicated layer is sandwiched between the outermost resin insulating interlayer and the inner resin insulating interlayer.

The package substrate may further contain a core substrate having a conductive layer. In such a structure, the inner resin insulating interlayer is formed on the core substrate, and the conductive layer of the core substrate corresponds to the second conductive layer. Yet furthermore, the package substrate of the embodiment may include a buildup layer between the core substrate and the inner resin insulating interlayer. In such a structure, the second conductive layer corresponds to conductive layer (58F) sandwiched between resin insulating interlayer (50F) on the core substrate and inner resin insulating interlayer (150Fa). A buildup layer includes resin insulating interlayers and conductive layers, which are laminated alternately. A package substrate having a core substrate and its manufacturing method are described in JP2007-227512A, for example. The entire contents of this publication are incorporated herein by reference. The entire contents of this publication are incorporated herein by reference. The package substrate of the embodiment may also be a coreless substrate. A coreless substrate includes resin insulating interlayers and conductive layers, which are laminated alternately. A coreless substrate and its manufacturing method are described in JP2005-236244A, for example. At least one conductive layer is designated as an dedicated wiring layer. The thickness of each resin insulating interlayer of a coreless substrate is 30 μm˜60 μm.

Package substrate 10 shown in FIG. 1 contains core substrate 30, the same as that shown in JP2007-227512A. Core substrate 30 contains insulative base (20z) having first surface (F) and second surface (S) opposite the first surface. Conductive layer (34F) is formed on first surface (F) of insulative base (20z), and conductive layer (34S) is formed on second surface (S). Insulative base (20z) has multiple penetrating holes 31, in which through-hole conductors 36 are formed to connect conductive layers (34F, 34S). Penetrating holes for forming through-hole conductors are shaped like an hourglass, the same as described in JP2007-227512A.

First buildup layer (55F) is formed on first surface (F) of core substrate 30. The first surface of the core substrate corresponds to the first surface of the insulative base. First buildup layer (55F) includes resin insulating interlayer (upper resin insulating interlayer) (50F) formed on core substrate 30, second conductive layer (58F) formed on resin insulating interlayer (50F), and via conductors (60F) penetrating through resin insulating interlayer (50F) and connecting second conductive layer (58F) and conductive layer (34F).

First buildup layer (55F) further includes inner resin insulating interlayer (150Fa) formed on resin insulating interlayer (50F) and on second conductive layer (58F), and first conductive layer (158Fa) formed on inner resin insulating interlayer (150Fa). First conductive layer (158Fa) is a dedicated wiring layer. There is no via conductor that penetrates only through inner resin insulating interlayer (150Fa). In addition, the first buildup layer further includes uppermost resin insulating interlayer (outermost resin insulating interlayer) (150Fb) formed on inner resin insulating interlayer (150Fa) and first conductive layer (158Fa), uppermost conductive layer (outermost conductive layer) (158Fb) formed on uppermost resin insulating interlayer (150Fb), via conductors (uppermost via conductors) (160Fa) penetrating through the uppermost resin insulating interlayer to connect the uppermost conductive layer and first conductive layer, and skip-via conductors (160Fb) penetrating through both the uppermost resin insulating interlayer and the inner resin insulating interlayer to connect the uppermost conductive layer and the second conductive layer. The uppermost conductive layer includes first pads (73Ff) for mounting a first electronic component and second pads (73Fs) for mounting a second electronic component. The uppermost via conductors include first via conductors (uppermost first via conductors) (160Faf) for connecting the first pads and the first conductive layer, as well as second via conductors (uppermost second via conductors) (160Fas) for connecting the second pads and the first conductive layer. The skip-via conductors include first skip-via conductors (160Fbf) for connecting the first pads and the second conductive layer, and second skip-via conductors (160Fbs) for connecting the second pads and the second conductive layer. Dedicated wiring layers are preferred to be formed only in the first buildup layer.

Second buildup layer (55S) is formed on second surface (S) of core substrate 30. Second buildup layer (55S) includes resin insulating interlayers and conductive layers, which are alternately laminated. The first and second buildup layers are preferred to be symmetrical at the core substrate.

Solder-resist layer (70F) having openings (71F) is formed on first buildup layer (55F), and solder-resist layer (70S) having openings (71S) is formed on second buildup layer (55S). First pads (73Ff) and second pads (73Fs) are exposed through openings (71F) of solder-resist layer (70F) formed on first buildup layer (55F). Solder bumps (first solder bumps) (76Ff) are formed on first pads (73Ff), and solder bumps (second solder bumps) (76Fs) are formed on second pads (73Fs). The fusing point of first solder bumps is preferred to be different from that of second solder bumps. Mounting yield and connection reliability are enhanced. In addition, it is easier to replace electronic components. Solder bumps (third solder bumps) (76S) for connection with a motherboard are formed on pads (73S) exposed through openings (71S) of solder-resist layer (70S) formed on second buildup layer (55S). Metal film 72 made of Ni/Au, Ni/Pd/Au or the like is formed on pads (73Ff, 73Fs, 73S). As shown in FIGS. 2 and 10B, IC chip (110L) is mounted on solder bumps (76Ff) for mounting an IC chip, and memory (110M) is mounted on solder bumps (76Fs) for mounting a memory. Package substrate 10 is mounted on a motherboard through solder bumps (76S) formed on the second buildup layer. The fusing points of the first, second and third solder bumps are preferred to be different from each other. Such a setting increases mounting yield and connection reliability.

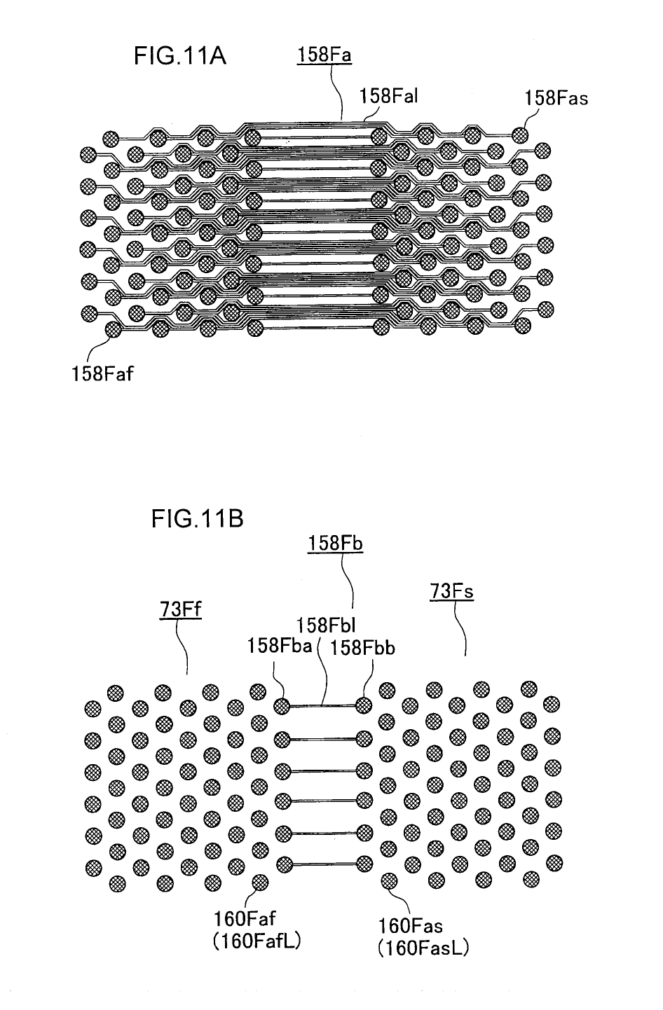

FIG. 11A is a plan view showing part of dedicated wiring layer (first conductive layer) (158Fa). FIG. 11A corresponds to a cross-sectional view taken along the (X1-X1) line in FIG. 1. The round conductors in FIG. 11A are pads. The pads on the left are first via-conductor pads (158Faf) and those on the right are second via-conductor pads (158Fas). First via conductors (160Faf) are formed on first via pads, and second via conductors (160Fas) are formed on second via pads. First conductive layer (158Fa) includes first conductive circuits (158Fal) each connecting a first via-conductor pad (158Faf) and a second via-conductor pad (158Fas). In the package substrate of the first embodiment, all data transmission between a first electronic component such as a logic chip and a second electronic component such as a memory chip is carried out mainly through first conductive layer (158Fa).

In the package substrate of the first embodiment, first conductive layer (158Fa) is set at a finer pitch than that of other conductive layers to increase its wiring density. Thus, the wiring width is narrow (for example, approximately 3˜11 μm, most preferably 5 μm) and wiring lines are made thin (for example, approximately 3˜11 μm, most preferably 5 μm). The area of the first conductive layer in contact with the inner resin insulating interlayer is 3˜15% of the area of the upper surface of the inner resin insulating interlayer (the area of the package substrate). A contact area of less than 3% causes greater variations in the plating thickness, and thinner wiring lines tend to break, making it harder to achieve connection reliability. On the other hand, a contact area exceeding 15% causes the volumes of conductive circuits to be different and unbalanced on the upper and lower surfaces of the package substrate. Namely, the upper-side copper volume is more than that on the lower side, causing upper-side rigidity to be higher than lower-side rigidity. As a result, the substrate is more likely to warp because of thermal stress. By setting the contact area at 3˜15%, warping is less likely to occur, and higher connection reliability is achieved.

First conductive circuits (158Fal) are set to be microstrip lines because of planar layer (58Fp) included in the second conductive layer. Accordingly, transmission properties of the first conductive circuits are enhanced.

The inner resin insulating interlayer is set to have a different thickness from the rest of resin insulating interlayers. Among resin insulating interlayers, resin insulating interlayers other than the inner resin insulating interlayer all have the same thickness. The thickness of an resin insulating interlayer is equal to the distance between adjacent conductive layers. In FIG. 1, thickness (t1) of outermost resin insulating interlayer (150Fb) is equal to thickness (t3) of upper resin insulating interlayer (50F). Thicknesses (t1, t3) of resin insulating interlayers other than the inner resin insulating interlayer are 15 μm˜40 μm. Thickness (t2) of the inner resin insulating interlayer is 7.5 μm˜20 μm. Thickness (t2) of the inner resin insulating interlayer is one-half to two-thirds of the thicknesses (t1, t3) of the rest of resin insulating interlayers. Skip-via conductors are formed at a fine pitch. Skip-via conductors are less likely to decrease the space for forming conductive circuits in the first conductive layer. The size of the package substrate is reduced. For example, thickness (t2) of inner resin insulating interlayer (150Fa) is 13 μm and the thickness of the rest of the resin insulating interlayers is 35 μm.

FIG. 11B is a plan view showing part of outermost conductive layer (158Fb). FIG. 11B corresponds to a cross-sectional view taken along the (X2-X2) line in FIG. 1. The round conductors in FIG. 11B are lands. The lands on the left side are lands (160FafL) of first via conductors (160Faf) and first lands (158Fba) for forming first pads (73Ff). First pads (73Ff) are portions of first lands (158Fba) and lands (160FafL) exposed through openings (71F) of upper solder-resist layer (70F). The lands on the right side are lands (160FasL) of second via conductors (160Fas) and second lands (158Fbb) for forming second pads (73Fs). Second pads (73Fs) are portions of second lands (158Fbb) and lands (160FasL) exposed through openings (71F) of upper solder-resist layer (70F). First lands (158Fba) and second lands (158Fbb) are connected by outermost conductive circuits (158Fb1). Outermost conductive layer (158Fb) includes first lands (158Fba), second lands (158Fbb) and outermost conductive circuits (158Fb1). In the package substrate of the first embodiment, data transmission between a first electronic component such as a logic chip and a second electronic component such as a memory chip is carried out through first conductive layer (158Fa) shown in FIG. 11A as well as through outermost conductive layer (158Fb) shown in FIG. 11B. Accordingly, the package substrate is capable of handling a greater volume of signal transmissions.

In the package substrate of the first embodiment, a dedicated wiring layer is formed directly under outermost resin insulating interlayer (150Fb), reducing the wiring distance between electronic components, and thereby increasing signal transmission speeds between the electronic components. Since the package substrate of the embodiment has dedicated wiring layers, the electrical characteristics of signal lines become similar, achieving uniform transmission time of signals in bytes. Signals are properly transmitted even at a higher transmission speed. Processing time will not be delayed even with a greater volume of transmission data. The package substrate of the embodiment does not include via conductors that penetrate only through the inner resin insulating interlayer, but includes skip vias that penetrate through both the inner resin insulating interlayer and the resin insulating interlayer positioned on the inner resin insulating interlayer. The size of the package substrate is reduced. The transmission time for signals in bytes is uniform. Signals are properly transmitted even at a higher signal transmission speed. Signal processing time is not delayed even with a greater volume of data.

The package substrate of the first embodiment has two dedicated layers for data transmission: namely, conductive circuits (158Fbl) of outermost conductive layer (158Fb) and first conductive circuits (158Fal) of first conductive layer (158Fa). With only one dedicated layer, the substrate size increases when there is a greater number of I/O's, and the wiring distance may be made longer. Accordingly, fine data transmission lines may cause wiring breakage and signal delays, and noise may be superimposed thereon. On the other hand, three or more dedicated wiring layers increase the substrate thickness, and may cause warping or undulation. Thus, fine data transmission lines may be damaged. In addition, when the number of wiring layers for data transmission is increased, signals may be delayed or noise may be superimposed thereon, thus causing malfunctions. By using an resin insulating interlayer with a seed layer, fine patterns are formed. Thus, even with a greater number of I/O's, two dedicated layers are enough.

### Method for Manufacturing Package Substrate of First Embodiment

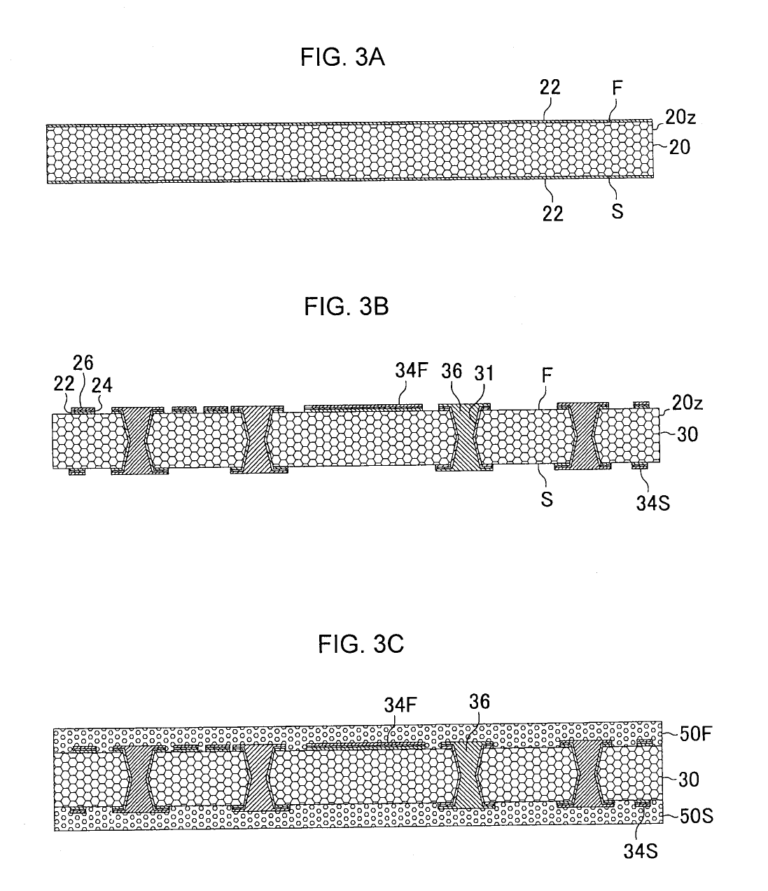

FIG. 3˜9 show a method for manufacturing package substrate 10 of the first embodiment.

(1) A starting substrate 20 having first surface (F) and its opposing second surface (S) is prepared. The starting substrate is preferred to be a double-sided copper-clad laminate. A double-sided copper-clad laminate is made of insulative base (20z) having first surface (F) and its opposing second surface (S) along with metal foils (22, 22) laminated respectively on both surfaces (FIG. 3A). The starting substrate of the first embodiment is a double-sided copper-clad laminate. A black-oxide treatment is performed on the surface of copper foil 22.

Insulative base (20z) is made of resin and reinforcing material. Examples of reinforcing material are glass cloth, aramid fibers, glass fibers and the like. Examples of resin are epoxy resins, BT (bismaleimide triazine) resins, and the like.

(2) The double-sided copper-clad laminate is processed to form core substrate 30 having upper and lower conductive layers (34F, 34S) made up of metal foil 22, electroless plated film 24 and electrolytic plated film 26, and through-hole conductors 36 formed in penetrating holes 31 (FIG. 3B). The first surface of core substrate 30 corresponds to the first surface of insulative base (20z), and the second surface of core substrate 30 corresponds to the second surface of insulative base (20z). Core substrate 30 is manufactured by a method disclosed in U.S. Pat. No. 7,786,390, for example.

(3) Upper resin insulating interlayer (50F) is formed on first surface (F) of core substrate 30. Lower resin insulating interlayer (50S) is formed on second surface (S) of the core substrate (FIG. 3C). The resin insulating interlayers contain inorganic particles made of silica or the like and thermosetting resin such as epoxy resin. The resin insulating interlayers may also contain reinforcing material such as glass cloth. resin insulating interlayers (50F, 50S) are each approximately 35 μm thick.

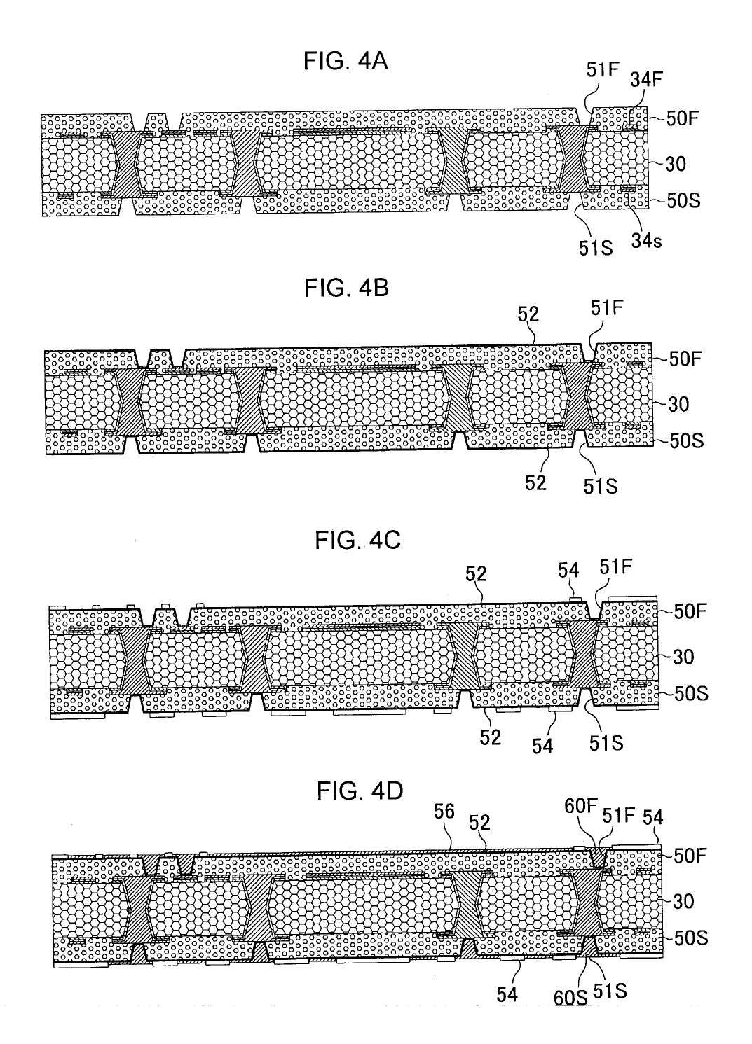

(4) Next, using a CO₂ gas laser, via-conductor openings (51F, 51S) are formed in resin insulating interlayers (50F, 50S) (FIG. 4A).

(5) Electroless copper-plated film 52 is formed on resin insulating interlayers (50F, 50S) and on the inner walls of openings (51F, 51S) (FIG. 4B).

(6) Plating resist 54 is formed on electroless copper-plated film 52 (FIG. 4C).

(7) Electrolytic copper-plated film 56 is formed on electroless copper-plated film 52 exposed from plating resist 54. During that time, openings (51F, 51S) are filled with electrolytic plated film 56. Via conductors (60F, 60S) are formed (FIG. 4D).

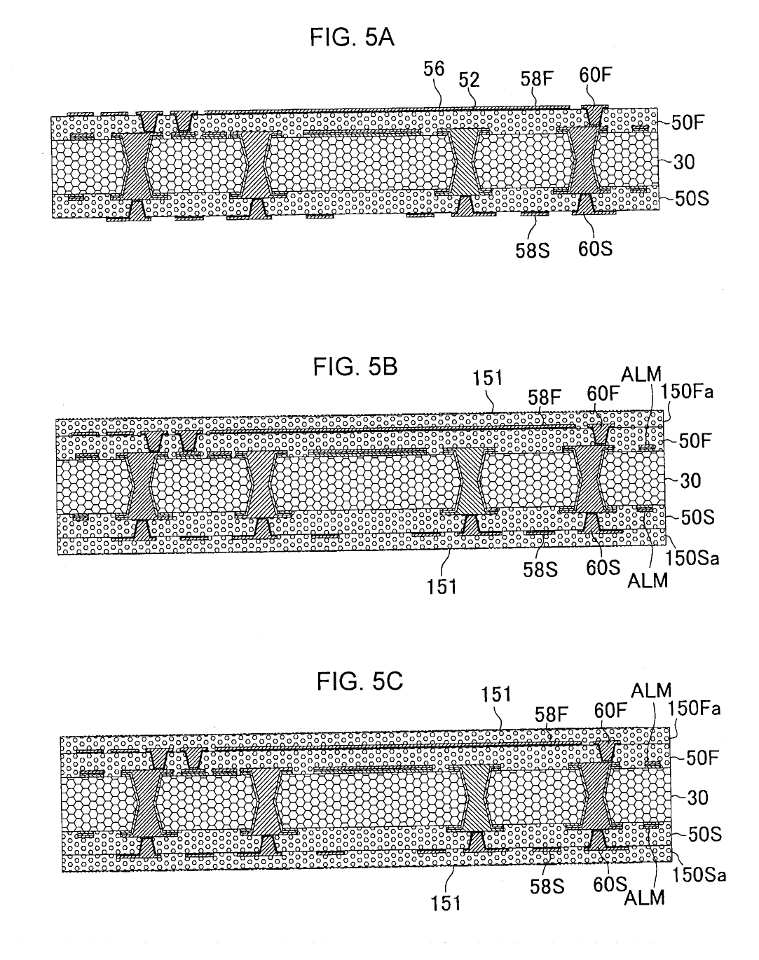

(8) Plating resist 54 is removed. Electroless plated film 52 exposed from electrolytic plated film 56 is removed. Second conductive layer (upper second conductive layer) (58F) is formed on resin insulating interlayer (50F). Second conductive layer (lower second conductive layer) (58S) is formed on resin insulating interlayer (50S) (FIG. 5A).

(9) B-stage resin film having a first surface and its opposing second surface is prepared. Seed layer 151 is formed by sputtering on the first surface of the resin film. Copper or the like is used to form the seed layer. The thickness of the seed layer (sputtered film) is 0.05 μm˜0.3 μm. The resin film with a seed layer is laminated on upper second conductive layer (58F) and upper resin insulating interlayer (50F) in such a way that the second surface of the resin film faces upper resin insulating interlayer (50F). Then, by curing the resin film, inner resin insulating interlayer (upper inner resin insulating interlayer) (150Fa) is formed on upper second conductive layer (58F) and on upper resin insulating interlayer (50F). In the embodiment, the upper inner resin insulating interlayer has a seed layer formed thereon.

The package substrate of the embodiment does not include via conductors penetrating only through the inner resin insulating interlayer. Thus, a seed layer can be formed on the resin film prior to a lamination processing of the film. Because the seed layer is formed by sputtering prior to lamination, it has a thin, uniform thickness. However, it is also an option to form the inner resin insulating interlayer first and then to form a seed layer thereon. The package substrate of the embodiment does not include via conductors penetrating only through the inner resin insulating interlayer. Accordingly, there is no need to form a seed layer on the inner walls of via-conductor openings when a seed layer is formed after the lamination process. As a result, the seed layer has a thin, uniform thickness. In the same manner, inner resin insulating interlayer (lower inner resin insulating interlayer) (150Sa) is formed on lower second conductive layer (58S) and lower resin insulating interlayer (50S) (FIG. 5B). In the embodiment, the lower resin insulating interlayer has a seed layer formed thereon. The thickness of inner resin insulating interlayers (150Fa, 150Sa) is 17 μm, approximately one-half of the thickness of resin insulating interlayers (50F, 50S).

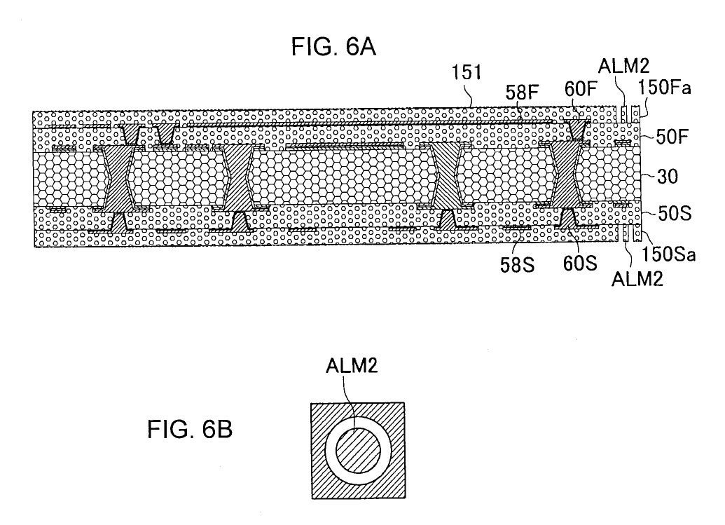

(10) Portions of the seed layer formed on the inner resin insulating interlayers are removed so that the seed layers on alignment marks (ALM) formed on the second conductive layers are removed (FIG. 5C). At that time, the seed layers to form later-described alignment marks (ALM2) are also removed. Based on the alignment marks formed on the second conductive layers, alignment marks (ALM2) are formed on the inner resin insulating interlayers (FIG. 6A). FIG. 6B shows an example of alignment mark (ALM2). The portion with slanted lines is a portion of the top surface of an inner resin insulating interlayer, and the empty portion is a groove. An alignment mark is formed with a portion of an inner resin insulating interlayer and a groove in the inner resin insulating interlayer. For example, an alignment mark is a ring-shaped groove formed in an inner resin insulating interlayer by using a laser.

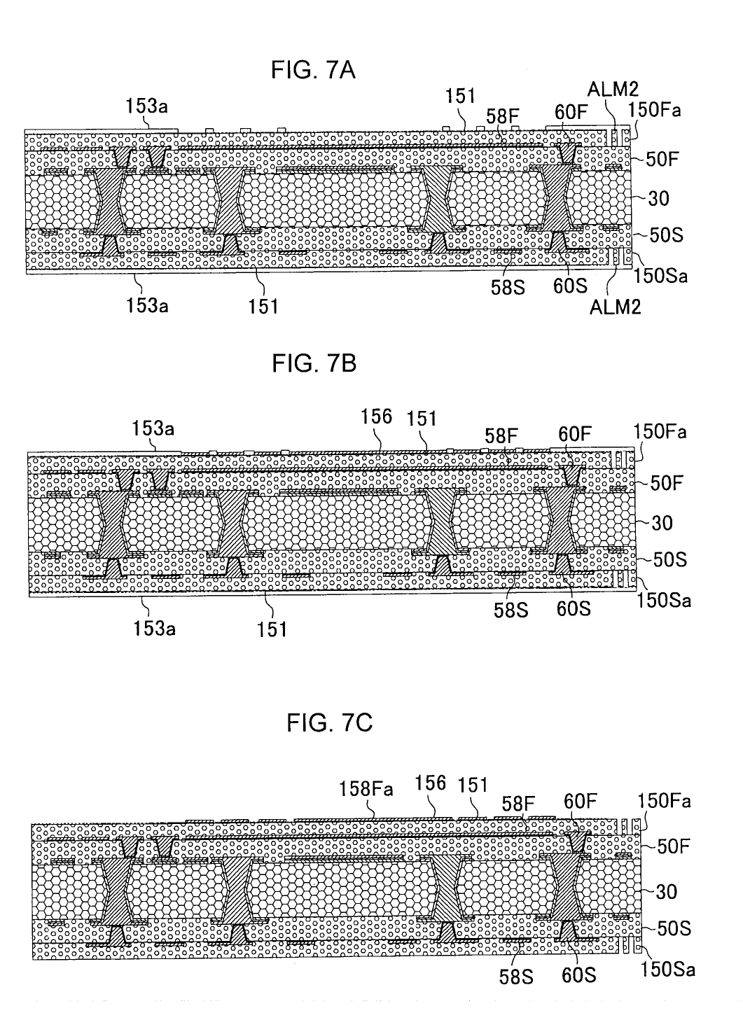

(11) Plating resist (153a) is formed on seed layer 151 based on alignment marks (ALM2) (FIG. 7A). Plating resist (153a) on the lower inner resin insulating interlayer is formed on the entire surface.

(12) Electrolytic copper-plated layer 156 is formed on seed layer 151 exposed from plating resist (153a) (FIG. 7B).

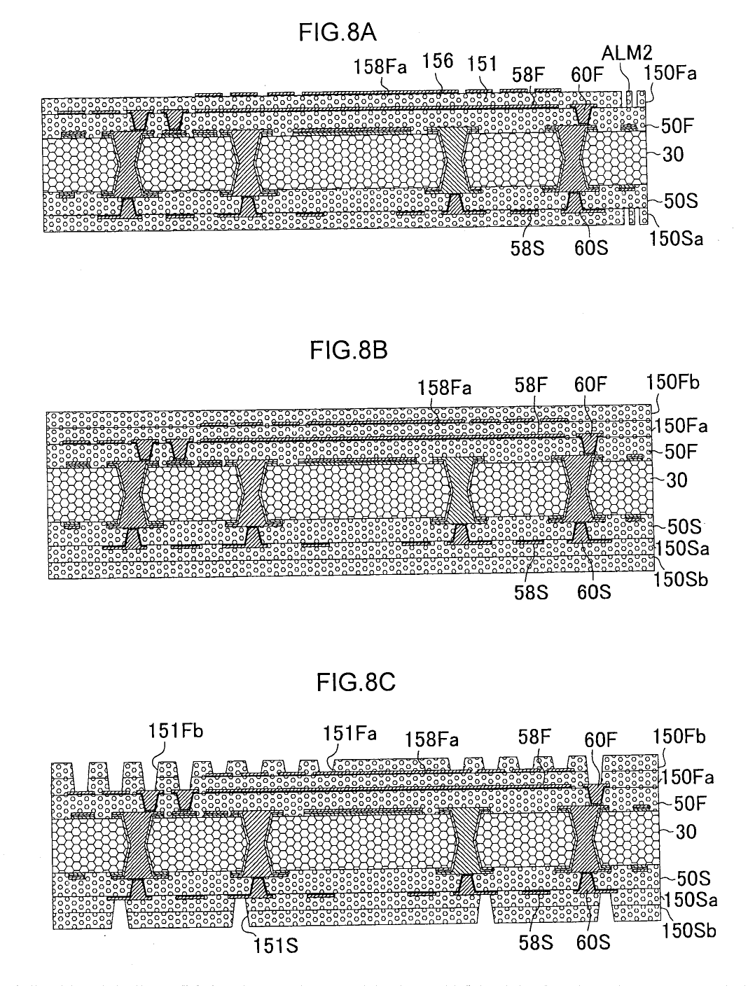

(13) Plating resist (153a) is removed (FIG. 7C). Seed layer 151 exposed from electrolytic copper-plated layer 156 is removed so that first conductive layer (upper first conductive layer) (158Fa) made up of seed layer 151 and electrolytic copper-plated layer 156 on the seed layer is formed on upper inner resin insulating interlayer (150Fa) (FIG. 8A). FIG. 11A is a plan view showing part of first conductive layer (158Fa). The L/S (line and space) of first conductive circuits in the first conductive layer is 5/5 μm, for example. First via-conductor pads (158Faf) and second via-conductor pads (158Fas) are also formed at that time. The first conductive layer also includes first alignment marks formed at the same time as the via-conductor pads. First alignment marks are not shown in the drawings. When the resin film for forming the lower inner resin insulating interlayer contains a seed layer, the seed layer is completely removed. Thus, the inner resin insulating interlayer in the second buildup layer is preferred to be formed with a resin film that does not contain a seed layer. No conductive layer is formed on the lower inner resin insulating interlayer.

(14) Outermost resin insulating interlayer (upper outermost resin insulating interlayer) (150Fb) is formed on the upper inner resin insulating interlayer and on the upper first conductive layer (dedicated wiring layer). Outermost resin insulating interlayer (lower outermost resin insulating interlayer) (150Sb) is formed on lower inner resin insulating interlayer (FIG. 8B). The thickness of resin insulating interlayers (150Fb, 150Sb) is the same as that of resin insulating interlayers (50F, 50S).

(15) Based on first alignment marks, a laser is used to form first openings (151Fa) penetrating through upper outermost resin insulating interlayer (150Fb) and reaching first conductive layer (158Fa) as well as to form second openings (151Fb) penetrating through both upper outermost resin insulating interlayer (150Fb) and upper inner resin insulating interlayer (150Fa) and reaching upper second conductive layer (58F). Also, openings (151S) are formed to penetrate through lower outermost resin insulating interlayer (150Sb) and lower inner resin insulating interlayer (150Sa) and to reach lower second conductive layer (58S) (FIG. 8C).

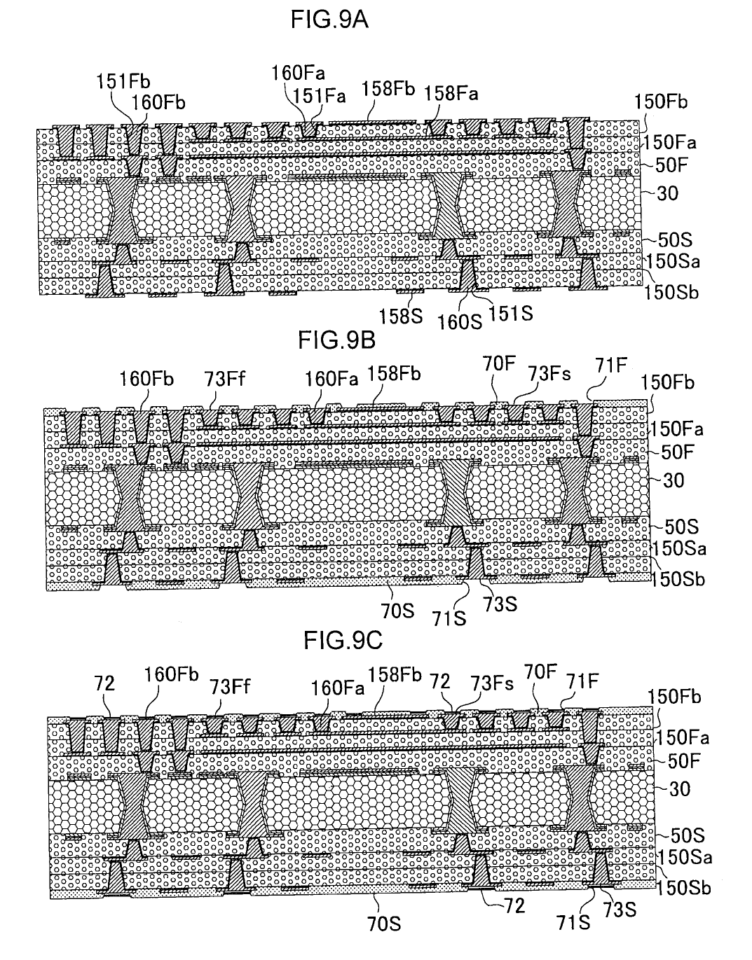

(16) Using a semi-additive method, via conductors (160Fa, 160Fb, 160S) are formed in via-conductor openings (151Fa, 151Fb, 151S). Also, outermost conductive layers (158Fb, 158S) are formed (FIG. 9A). FIG. 11B is a plan view showing part of outermost conductive layer (158Fb). Outermost conductive layer (158Fb) includes first lands (158Fba), second lands (158Fbb) and outermost conductive circuits (158Fb1). First lands (158Fba) and second lands (158Fbb) are connected by outermost conductive circuits (158Fbl). Via conductors (160Fb, 160S) are skip-via conductors, which penetrate through both outermost resin insulating interlayer and inner resin insulating interlayer at the same time and connect the outermost conductive layer and the second conductive layer. The outermost conductive layer and the first conductive layer are connected by via conductors (160Fa). The upper outermost conductive layer includes a first pad group and a second pad group. The second pad group is formed of first, second, third and fourth groups, which surround the first pad group as shown in FIG. 10. Each group in the second pad group is formed on an outer side of the first pad group.

(17) Upper solder-resist layer (70F) having openings (71F) is formed on the first buildup layer, and lower solder-resist layer (70S) having openings (71S) is formed on the second buildup layer (FIG. 9B). Top surfaces of first pads (73Ff) and second pads (73Fs) are exposed through openings (71F) of first solder-resist layer (70F). Meanwhile, top surfaces of the conductive layers and via lands exposed through openings (71S) of second solder-resist layer (70S) work as pads (73S) for connection with a motherboard.

(18) A nickel-plated layer is formed on pads (73Ff, 73Fs, 73S), and a gold-plated layer is further formed on the nickel-plated layer. Accordingly, metal layer 72 made of nickel- and gold-plated layers is formed (FIG. 9C). Instead of a nickel-gold layer, a nickel-palladium-gold layer or an OSP film may also be formed.

(19) Solder balls are mounted on pads (73Ff, 73Fs, 73S) and reflowed to form solder bumps (76Ff, 76Fs, 76S). Package substrate 10 is completed (FIG. 1).

(20) Logic IC chip (110L) is mounted on solder bumps (76Ff) on first pads, and memory (110M) is mounted on solder bumps (76Fs) on second pads (FIG. 2, FIG. 10B). Underfill 114 is filled between the package substrate and IC chip (110L) and memory (110M) (FIG. 2).

For manufacturing a package substrate of the first embodiment, a resin film with a seed layer is used for forming first conductive layer (158Fa) from the seed layer. Since a seed layer is formed on an independent single film, it is easier to control the thickness of a seed layer or variations in the thickness of the seed layer. Also, a seed layer may be formed by sputtering. The first conductive layer, which is set to be a dedicated wiring layer for data transmission, is made thinner. Since the seed layer is thin, the amount of etching of the seed layer is less when conductive circuits are formed. Accordingly, fine conductive circuits are formed in the first conductive layer. For example, fine signal lines with an L/S of 8 μm/8 μm or smaller are formed in the first conductive layer. Since no conductive layer is present on the lower inner resin insulating interlayer in the first embodiment, the lower inner resin insulating interlayer may be omitted. In such a structure, to reduce warping in the package substrate, an resin insulating interlayer in the second buildup layer is preferred to have a greater thickness than the rest of the resin insulating interlayers. The thickness of such a thicker resin insulating interlayer is obtained by adding the thickness of the upper inner resin insulating interlayer and the thickness of an resin insulating interlayer other than the upper inner resin insulating interlayer.

### Second Embodiment

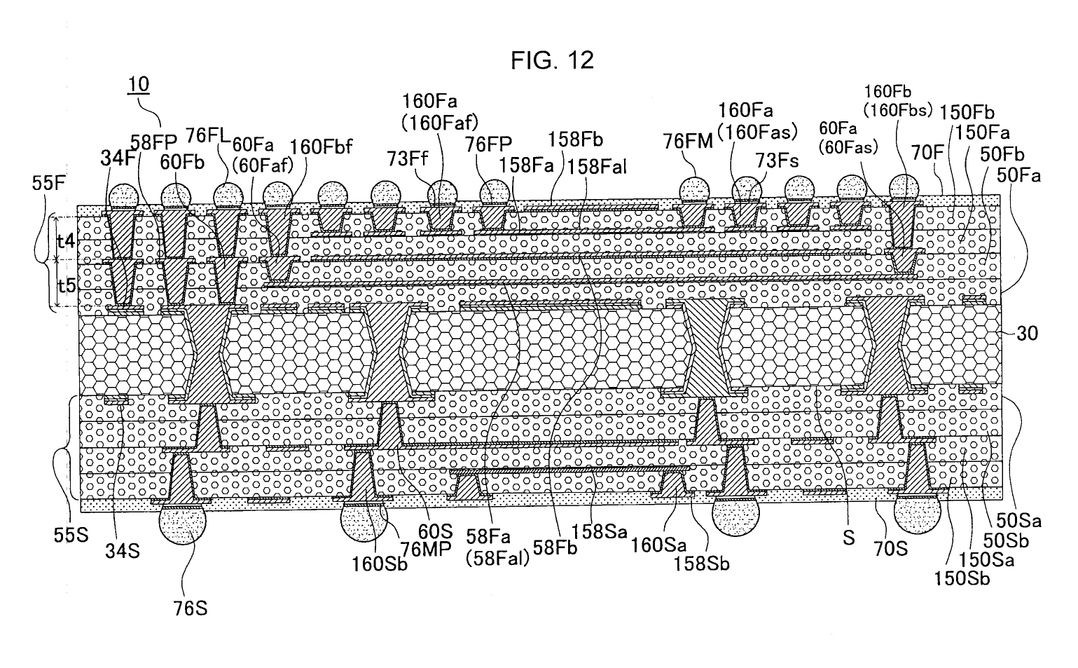

FIG. 12 shows a cross-sectional view of a package substrate according to a second embodiment.

The package substrate of the second embodiment contains outermost conductive layer (158Fb) that includes pads for mounting electronic components. The package substrate further contains outermost resin insulating interlayer (150Fb) to support outermost conductive layer (158Fb). Outermost resin insulating interlayer (150Fb) has an upper first surface and a lower second surface.

In outermost resin insulating interlayer (150Fb) of the second embodiment, first via conductors (160Faf) connected to first pads (73Ff) and second via conductors (160Fas) connected to second pads (73Fs) are formed. First pads (73Ff) and second pads (73Fs) are positioned the same as in the first embodiment shown in FIG. 10A. First conductive layer (158Fa) including multiple first conductive circuits (158Fal) is formed under outermost resin insulating interlayer (150Fb). First pads and second pads are connected through first conductive circuits. Namely, signal transmission or the like between first and second electronic components is carried out through the first conductive layer.

Second resin insulating interlayer (150Fa) is formed under first conductive layer (158Fa). Second conductive layer (58Fb) is formed under second resin insulating interlayer (150Fa). Third resin insulating interlayer (50Fb) is formed under second conductive layer (58Fb). Third conductive layer (58Fa) including multiple conductive circuits (58Fal) is formed under third resin insulating interlayer (50Fb). The same as the first conductive layer, third conductive layer (58Fa) is a dedicated wiring layer to carry out signal transmission or the like between the first and second electronic components. Fourth resin insulating interlayer (50Fa) is formed under third conductive layer (58Fa). Fourth conductive layer (upper conductive layer) (34F) is formed under fourth resin insulating interlayer (50Fa).

First skip-via conductors (160Fbf) are formed to penetrate through both outermost resin insulating interlayer (150Fb) and second resin insulating interlayer (150Fa) at the same time to connect first pads (73Ff) and second conductive layer (58Fb). Second skip-via conductors (160Fbs) are formed to penetrate through both outermost resin insulating interlayer (150Fb) and second resin insulating interlayer (150Fa) at the same time and to connect second pads (73Fs) and second conductive layer (58Fb). Third via conductors (60Faf) are each formed directly under a first skip-via conductor (160Fbf) to penetrate through third resin insulating interlayer (50Fb) and to connect second conductive layer (58Fb) and third conductive layer (58Fa). Fourth via conductors (60Fas) are each formed directly under a second skip-via conductor (160Fbs) to penetrate through third resin insulating interlayer (50Fb) and connect second conductive layer (58Fb) and third conductive layer (58Fa). Skip-via conductors (60Fb) are formed to penetrate through both third resin insulating interlayer (50Fb) and fourth resin insulating interlayer (50Fa) at the same time and to connect second conductive layer (58Fb) and fourth conductive layer (34F).

As described above, a first conductive circuit (158Fal), formed in first conductive layer (158Fa) that is set to be a dedicated wiring layer, connects a first pad (73Ff) in the first pad group and a second pad of the second pad group. A third conductive circuit (58Fal), formed in third conductive layer (58Fa) set to be a dedicated wiring layer, connects third via conductor (60Faf) connected to the first-pad (73Ff) side and fourth via conductor (60Fas) connected to the second-pad (73Fs) side.

In the package substrate of the second embodiment, thickness (t4) of an resin insulating interlayer between outermost conductive layer (158Fb) and second conductive layer (58Fb) is substantially the same as thickness (t5) of an resin insulating interlayer between second conductive layer (58Fb) and fourth conductive layer (34F).

The package substrate of the second embodiment has two dedicated layers for data transmission: namely, first conductive circuits (158Fal) of first conductive layer (158Fa) and third conductive circuits (58Fal) of third conductive layer (58Fa). When the number of I/O's is greater, the substrate size increases if there is only one dedicated layer, thereby increasing wiring distance as well. Since micro wiring lines are used for data transmission, the wiring lines may break, signal processing may be delayed and noise may be superimposed thereon. On the other hand, three or more dedicated layers make the substrate thicker, causing warping or undulation. Accordingly, micro wiring lines for data transmission may break. Also, a greater number of wiring layers for data transmission causes malfunctions derived from signal delays or superimposed noise. By using an resin insulating interlayer with a seed layer, fine patterns are formed. Thus, even with a greater number of I/O's, two dedicated layers are enough.

In the package substrate of the second embodiment, first conductive layer (158Fa) and third conductive layer (58Fa) are set to be dedicated wiring layers by skipping the second conductive layer. Thus, noise, which may occur when signals overlap, is reduced, and stable impedance is achieved.

The package substrate of the second embodiment is structured to sandwich first conductive layer (158Fa) between outermost conductive layer (158Fb) and second conductive layer (58Fb) and to sandwich third conductive layer (58Fa) between second conductive layer (58Fb) and fourth conductive layer (34F). Accordingly, strip line structures can be employed by setting outermost conductive layer (158Fb), second conductive layer (58Fb) and fourth conductive layer (34F) to be solid layers for ground. Electrical characteristics are enhanced.

In the second embodiment, first conductive layer (158Fa) and third conductive layer (58Fa) as dedicated wiring layers for data transmission are not formed as surface layers of a printed wiring board but are positioned as inner layers. As a result, variations in the insulation distance are suppressed between the dedicated wiring lines for data transmission and the wiring lines formed thereon, and it is easier to bring impedance characteristics to converge at a desired value.

### Method for Manufacturing Package Substrate of Second Embodiment

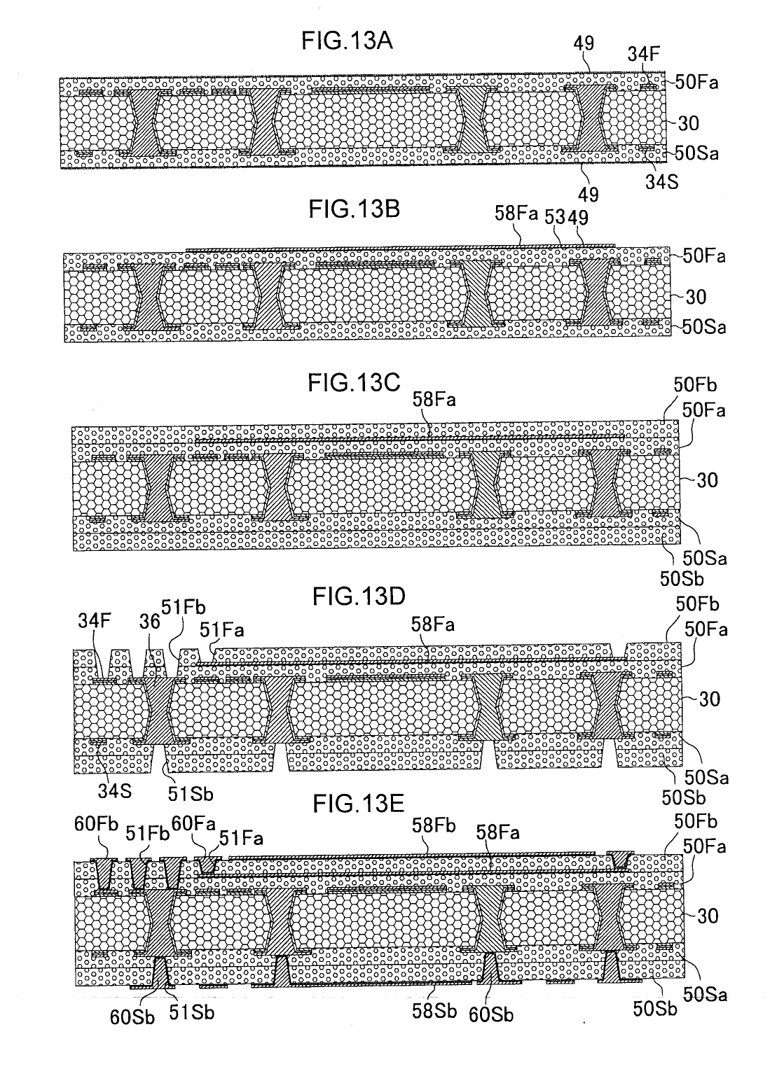

On both surfaces core substrate 30 shown in FIG. 3B, interlayer-insulation-layer film with transfer copper foil 49 is laminated and cured to form fourth resin insulating interlayers (50Fa, 50Fb) (FIG. 13A).

Next, third conductive layer (58Fa) is formed to be a dedicated wiring layer, the same as in the first embodiment shown in FIG. 7 (FIG. 13B). As described above, using interlayer-insulation-layer film with transfer copper foil, third conductive layer (58Fa) is formed to have a fine pitch.

Film for forming an resin insulating interlayer is laminated on fourth resin insulating interlayers and cured to form third resin insulating interlayers (50Fb, 50Sb) (FIG. 13C).

Using a laser, penetrating holes (51Fb) for skip-via conductors are formed to penetrate through both third resin insulating interlayer (50Fb) and fourth resin insulating interlayer (50Fa) to reach fourth conductive layer (34F) and through-holes 36. Also, penetrating holes (51Fa) for via conductors are formed by using a laser to penetrate through third resin insulating interlayer (50Fba) and to reach third conductive layer (58Fa) (FIG. 13D).

Using a semi-additive method, via conductors (60Fa, 60Sa) are formed in via-conductor openings (51Fa, 51Sb), and skip-via conductors (60Fb) are formed in penetrating holes (51Fb) for skip-via conductors. In addition, second conductive layers (58Fb, 58Sb) are formed (FIG. 13E). Since the subsequent steps are the same as those in the first embodiment, their descriptions are omitted here.

### Third Embodiment

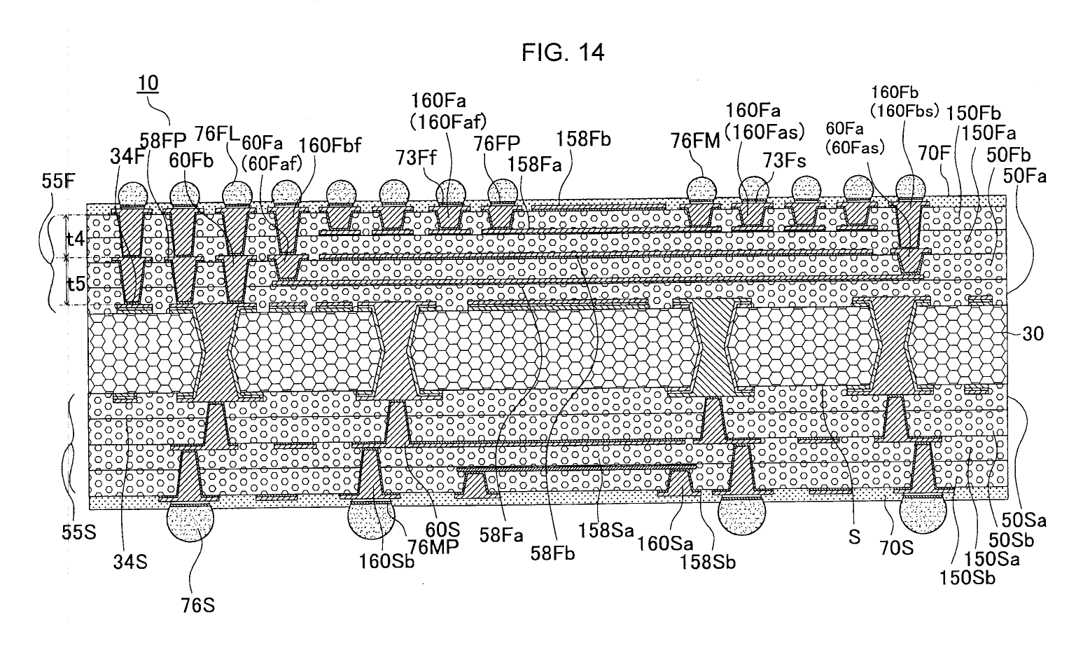

FIG. 14 shows a cross-sectional view of a package substrate according to a third embodiment. The layer structures in the third embodiment are the same as those in the second embodiment. However, second conductive layer (58Fb) and third conductive layer (58Fa) are used as dedicated wiring layers for data transmission in the third embodiment. The same effects as those in the second embodiment are also achieved in the third embodiment.

### Fourth Embodiment

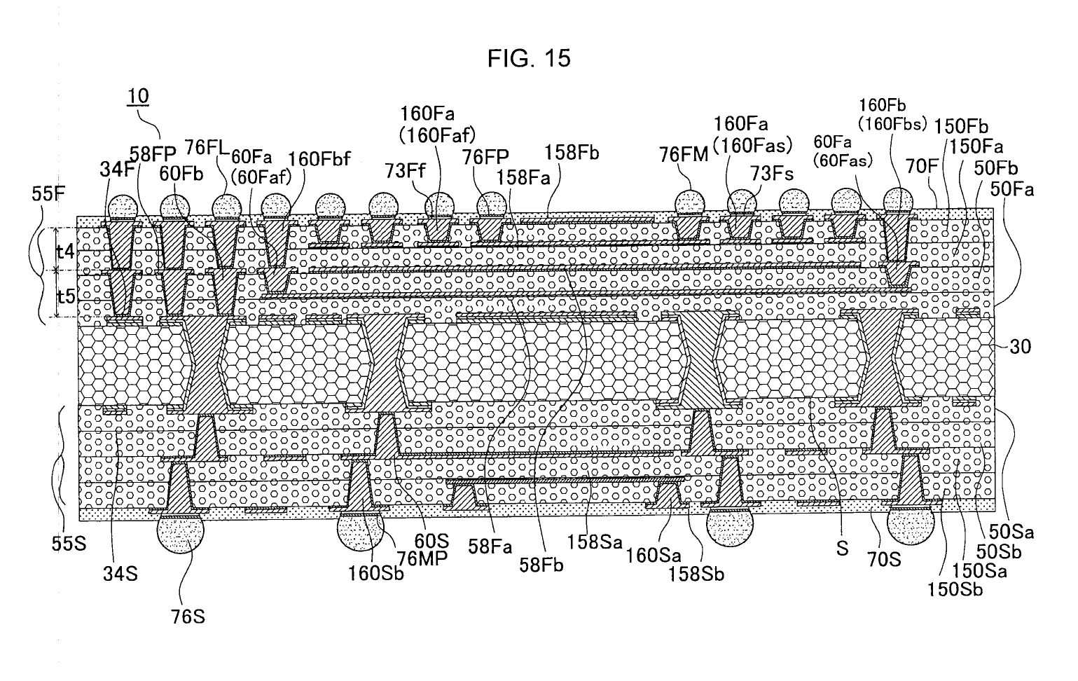

FIG. 15 shows a cross-sectional view of a package substrate according to a fourth embodiment. The layer structures in the fourth embodiment are the same as those in the second embodiment. However, first conductive layer (158Fa) and second conductive layer (58Fb) are formed as dedicated wiring layers for data transmission in the fourth embodiment. The same effects as those in the second embodiment are also achieved in the fourth embodiment.

A multi-chip module may include four wiring layers, and when all four layers have wiring lines that connect two LSIs, of the four wiring layers, at least one wiring layer may have a power line or a ground line and a wiring line that connects two LSIs and it may be difficult for such a multi-chip module to increase transmission speeds between electronic components.

A package substrate according to an embodiment of the present invention is capable of achieving faster signal transmission speeds and greater signal transmission volume between electronic components.

A package substrate according to an embodiment of the present invention is formed by alternately laminating resin insulating interlayers and four or more conductive layers and mounts two electronic components. The conductive layers include two dedicated wiring layers connecting two electronic components for data transmission. Only two dedicated wiring layers are formed for data transmission.

Obviously, numerous modifications and variations of the present invention are possible in light of the above teachings. It is therefore to be understood that within the scope of the appended claims, the invention may be practiced otherwise than as specifically described herein.

What is claimed is:

1. A package substrate, comprising:
a plurality of resin insulating interlayers; and
at least four conductive layers comprising a plurality of dedicated wiring layers such that the plurality of dedicated wiring layers is consisting of two dedicated wiring layers configured to transmit data between a first electronic component and a second electronic component connected by the two dedicated wiring layers.

2. A package substrate according to claim 1, further comprising:
a plurality of first via conductors formed through an outermost resin insulating interlayer of the resin insulating interlayers;
a plurality of second via conductors formed through the outermost resin insulating interlayer of the resin insulating interlayers;
a plurality of first skip via conductors formed through the outermost resin insulating interlayer and a second resin insulating interlayer on which the outermost resin insulating interlayer is laminated;
a plurality of second skip via conductors formed through the outermost resin insulating interlayer and the second resin insulating interlayer on which the outermost resin insulating interlayer is laminated;
a plurality of third via conductors formed through a third resin insulating interlayer on which the second resin insulating interlayer is laminated; and
a plurality of fourth via conductors formed through a third resin insulating interlayer on which the second resin insulating interlayer is laminated,
wherein the at least four conductive layers comprise an outermost conductive layer, a first conductive layer formed on the second resin insulating interlayer, a second conductive layer formed on the third resin insulating interlayer and a third conductive layer on which the third resin insulating interlayer is formed, the outermost conductive layer comprises a plurality of first pads and a plurality of second pads formed such that the plurality of first pads is positioned to mount the first electronic component and that the plurality of second pads is positioned to mount the second electronic component, the first conductive layer comprises a plurality of first conductive circuits formed such that the plurality of first conductive circuits is connecting the plurality of first pads and the plurality of second pads, respectively, the third conductive layer comprises a plurality of third conductive circuits formed such that the plurality of third conductive circuits is connecting the plurality of third via conductor and the plurality of fourth via conductors, the plurality of first via conductors is connected to a group of the first pads, the plurality of second via conductors is connected to a group of the second pads, the plurality of first skip via conductors is connecting a group of the first pads and the second conductive layer, the plurality of second skip via conductors is connecting a group of the second pads and the second conductive layer, the plurality of third via conductors is formed directly underneath the plurality of first skip via conductors respectively such that the plurality of third via conductor is connecting the second conductive layer and the third conductive layer, and the plurality of fourth via conductors is formed directly underneath the plurality of second skip via conductors respectively such that the plurality of fourth via conductors is connecting the second conductive layer and the third conductive layer.

3. A package substrate according to claim 2, further comprising:
a plurality of skip via conductors formed through the third resin insulating interlayer and a fourth resin insulating interlayer of the resin insulating interlayers such that the plurality of skip via conductors is connecting the second conductive layer and a fourth conductive layer of the at least four conductive layers.

4. A package substrate according to claim 2, wherein the first conductive layer is consisting of the plurality of first conductive circuits forming a first dedicated wiring layer of the two dedicated wiring layers, and the third conductive layer is consisting of the plurality of third conductive circuits forming a second dedicated wiring layer of the two dedicated wiring layers.

5. A package substrate according to claim 4, wherein the two dedicated wiring layers are formed such that one of the resin insulating interlayers is interposed between the two dedicated wiring layers.

6. A package substrate according to claim 1, wherein the at least four conductive layers includes an outermost conductive layer comprising one of the two dedicated wiring layers.

7. A package substrate according to claim 3, wherein the plurality of resin insulating interlayers is formed such that a thickness of resin insulating interlayers between the outermost conductive layer and the second conductive layer is substantially equal to a thickness of resin insulating interlayers between the second conductive layer and the fourth conductive layer.

8. A package substrate according to claim 1, wherein the first electronic component is a logic IC component, and the second electronic component is a memory component.

9. A package substrate according to claim 1, wherein the at least four conductive layers comprise an outermost conductive layer and a first conductive layer, the outermost conductive layer comprises a plurality of first pads and a plurality of second pads formed such that the plurality of first pads is positioned to mount the first electronic component and that the plurality of second pads is positioned to mount the second electronic component, the first conductive layer comprises a plurality of first conductive circuits formed such that the plurality of first conductive circuits is connecting the plurality of first pads and the plurality of second pads, respectively.

10. A package substrate according to claim 9, wherein the first conductive layer is consisting of the plurality of first conductive circuits forming a first dedicated wiring layer of the two dedicated wiring layers, and the at least four conductive layers comprise a third conductive layer consisting of a plurality of third conductive circuits forming a second dedicated wiring layer of the two dedicated wiring layers.

11. A package substrate according to claim 10, wherein the two dedicated wiring layers are formed such that one of the resin insulating interlayers is interposed between the two dedicated wiring layers.

12. A package substrate according to claim 9, wherein the outermost conductive layer comprises one of the two dedicated wiring layers.

13. A package substrate according to claim 9, wherein the first electronic component is a logic IC component, and the second electronic component is a memory component.

14. A package substrate according to claim 2, wherein the first electronic component is a logic IC component, and the second electronic component is a memory component.

15. A package substrate according to claim 9, further comprising:
a plurality of first via conductors formed through an outermost resin insulating interlayer of the resin insulating interlayers such that the plurality of first via conductors is connected to a group of the first pads; and
a plurality of second via conductors formed through the outermost resin insulating interlayer of the resin insulating interlayers such that the plurality of second via conductors is connected to a group of the second pads.

16. A package substrate according to claim 15, further comprising:
a plurality of first skip via conductors formed through the outermost resin insulating interlayer and a second resin insulating interlayer on which the outermost resin insulating interlayer is laminated; and
a plurality of second skip via conductors formed through the outermost resin insulating interlayer and the second resin insulating interlayer on which the outermost resin insulating interlayer is laminated,
wherein the at least four conductive layers comprise a second conductive layer, the plurality of first skip via conductors is connecting a group of the first pads and the second conductive layer, and the plurality of second skip via conductors is connecting a group of the second pads and the second conductive layer.

17. A package substrate according to claim 15, wherein the first conductive layer is consisting of the plurality of first conductive circuits forming a first dedicated wiring layer of the two dedicated wiring layers, and the at least four conductive layers comprise a third conductive layer consisting of a plurality of third conductive circuits forming a second dedicated wiring layer of the two dedicated wiring layers.

18. A package substrate according to claim 16, wherein the first conductive layer is consisting of the plurality of first conductive circuits forming a first dedicated wiring layer of the two dedicated wiring layers, and the at least four conductive layers comprise a third conductive layer consisting of a plurality of third conductive circuits forming a second dedicated wiring layer of the two dedicated wiring layers.

19. A package substrate according to claim 17, further comprising:
a plurality of third via conductors formed through a third resin insulating interlayer on which the second resin insulating interlayer is laminated; and
a plurality of fourth via conductors formed through a third resin insulating interlayer on which the second resin insulating interlayer is laminated,
wherein the plurality of third via conductors is formed directly underneath the plurality of first skip via conductors respectively such that the plurality of third via conductor is connecting the second conductive layer and the third conductive layer, and the plurality of fourth via conductors is formed directly underneath the plurality of second skip via conductors respectively such that the plurality of fourth via conductors is connecting the second conductive layer and the third conductive layer.

20. A package substrate according to claim 18, further comprising:
a plurality of third via conductors formed through a third resin insulating interlayer on which the second resin insulating interlayer is laminated; and
a plurality of fourth via conductors formed through a third resin insulating interlayer on which the second resin insulating interlayer is laminated,
wherein the plurality of third via conductors is formed directly underneath the plurality of first skip via conductors respectively such that the plurality of third via conductor is connecting the second conductive layer and the third conductive layer, and the plurality of fourth via conductors is formed directly underneath the plurality of second skip via conductors respectively such that the plurality of fourth via conductors is connecting the second conductive layer and the third conductive layer.
